(19) United States
(12) Patent Application Publication
(10) Pub. No.: US 2006/0273932 A1
(43) Pub. Date: Dec. 7, 2006

(54) Data entry apparatus and method

(76) Inventor: Nathan C. Wise, Davidsonville, MD (US)

Correspondence Address: SHOEMAKER AND MATTARE, LTD, 10 POST OFFICE ROAD - SUITE 110, SILVER SPRING, MD, 20910, US

(21) Appl. No.: 11/142,382

(22) Filed: Jun. 2, 2005

(51) Int. Cl. H03K 17/94; H03M 11/00

(52) U.S. Cl. 341/20

(57) ABSTRACT

Each of a number of independently-operated input buttons is actuable in five directions and a unique output response is associated with each of the directions. Preferably, there are five finger buttons and at least one thumb button. The five-position thumb button can be used to shift the key assignments of the finger buttons and thus greatly enlarge the size of the response set. The apparatus may be configured to receive a mouse, or it may be incorporated into a cell phone.

### BACKGROUND OF THE INVENTION

Many data entry devices exist for entering alphanumeric input into computer-based devices, such as desktop and laptop computers, personal digital assistants (PDA) and cellular telephones. Often, the physical arrangement and/or unique data entry conventions render use of the data entry devices difficult or easily confused with others. Existing systems usually suffer from one or more of the following drawbacks: large size, difficulty of learning, difficulty of use, awkward operation, lack of accuracy in input operation, and inability to handle character input, command input, and modified character input.

For over a century the “qwerty” keyboard, named for the first six letters along the top row, has been the standard input device for text. A version, termed “Multi-Functional Keyboard, Version 2” was developed and defined by International Business Machines, Inc. (IBM) for use with Intel-compatible personal computers (PCs). This version has become a standard computer keyboard. This keyboard also has been modified to have a more compact layout for laptops and PDAs, or a few extra keys.

The standard computer keyboard has significant disadvantages. To operate almost all keys, a user must move a finger to a particular key position for a desired entry. This requires error-prone finger movement. Users unfamiliar with the letter layout, purposely designed to slow typing to prevent jamming of the mechanisms of early mechanical typewriters, have to search for letters. Consequently, the keyboard is difficult to use for first-time users. To type text somewhat efficiently, a user has to memorize the positions of the chaotically arranged letters. Learning such positions is difficult and requires considerable training.

Modern graphical user interfaces typically involve a mouse and pull-down menus. A mouse is device for moving a pointer or cursor on a computer screen. Alternatives to the mouse include a touch pad, track ball, and joystick. A pointing device is efficient at positioning a cursor at a position on a display because both move in two dimensions, enabling an operator to instantly map an intended movement of the cursor to a corresponding swift movement operation of the pointing device. Pointing devices are inefficient for menu and menu item selection, for which they are mainly used with graphical user interfaces. Using a mouse in combination with the standard computer keyboard requires the operator to switch between the two. This is inefficient, slow, and awkward.

The need to use a pointing device for selection purposes with graphical user interfaces is due to shortcomings of the standard computer keyboard. For selection of symbols not present on the standard computer keyboard, a pointing device in combination with a graphical user interface is easier to operate than the standard computer keyboard. Menus and menu items displayed by a graphical user interface, in many cases, also can be selected by pressing combinations of keys on the standard computer keyboard. But the key combinations are difficult to remember and/or execute.

What are needed, and not taught or suggested in the art, are a universal data entry apparatus and method that provide for ergonomic, one-handed data entry in any electronic device with logical input device actuation-data entry associations.

### SUMMARY OF THE INVENTION

The invention overcomes the disadvantages noted above by providing a universal data entry apparatus and method that provide for ergonomic, one-handed data entry in any electronic device with logical input device actuation-data entry associations.

To that end, an apparatus for entering data according to this invention includes plural (preferably five) independently-operated primary input devices (finger buttons) for entering a set of responses, wherein each of the input devices is actuable in five directions, and a unique primary response of the set is associated with each of the directions. This arrangement provides twenty-five different primary outputs.

Another embodiment of the invention includes at least one secondary input device (thumb button) that is actuable in at least one (preferably five) directions, wherein a unique secondary response is associated with each of the plurality of directions, and each secondary response shifts the responses of the primary input devices. This arrangement provides the possibility of 125 different outputs, more than enough to represent all the upper and lower case Arabic characters, the numerals and common punctuation marks.

An advantage of the invention is that it enables one to input data with one hand only, and at a rapid rate.

Other features and advantages of the invention will become apparent from the following description of the preferred embodiments, which refers to the accompanying drawings.

### BRIEF DESCRIPTION OF THE DRAWINGS

The invention is described in detail below with reference to the following figures, throughout which similar reference characters denote corresponding features consistently, wherein:

FIG. 1 is a plan view of an embodiment of a data entry apparatus configured according to principles of the invention;

FIG. 2 is a plan view of another embodiment of a data entry apparatus configured to receive a mouse drawn in broken lines;

FIG. 3 is schematic view of input device actuation-data entry associations configured according to principles of the invention;

FIG. 4 is a schematic view of an embodiment of a data entry method configured according to principles of the invention;

FIGS. 5a and 5b depict, respectively front and rear surfaces of a cell phone having a keyboard embodying the invention; and

FIG. 6 shows a multiple-key alternative for each input device, in lieu of the five-position keys shown in the other drawings.

### DETAILED DESCRIPTION OF THE PREFERRED EMBODIMENTS

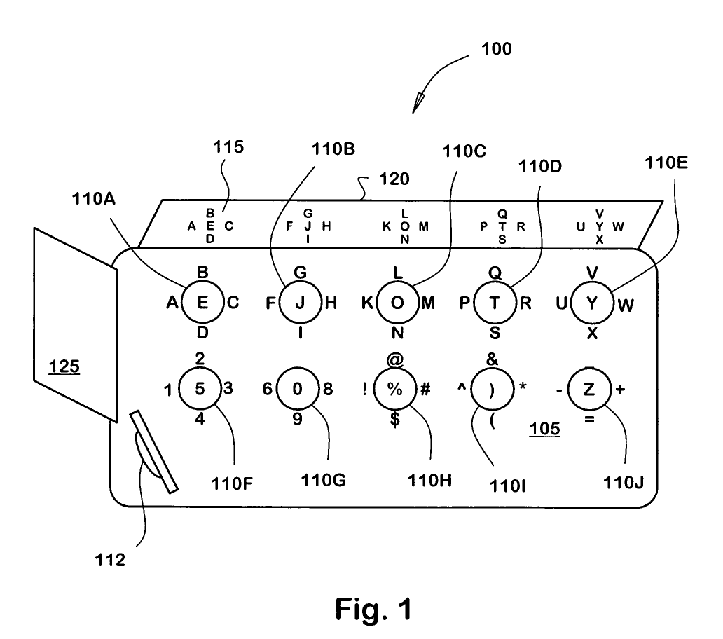

Referring to FIG. 1, an apparatus 100 for entering data includes a keyboard 105 on or in which are mounted a plurality of keys or input devices 110. The keys in this embodiment are arranged in two rows of five.

Each key 110 is actuable in at least five directions. One may toggle left, toggle away, toggle right, toggle toward or depress each key 110. Actuating each key 110 in any one of the five directions yields a uniquely associated response. The number of keys 110 must be sufficient for entering a response set.

For example, for entering alphabetic data, key 110A may be configured so that: toggling left yields “a”; toggling up yields “b”; toggling right yields “c”; toggling down yields “d”; and depressing yields “e”. Key 110B may be configured so that: toggling left yields “f”; toggling up yields “g”; toggling right yields “h”; toggling down yields “i”; and depressing yields “j”. Key 110C may be configured so that: toggling left yields “k”; toggling up yields “l”; toggling right yields “m”; toggling down yields “n”; and depressing yields “o”. Key 110D may be configured so that: toggling left yields “p”; toggling up yields “q”; toggling right yields “r”; toggling down yields “s”; and depressing yields “t”. Key 110E may be configured so that: toggling left yields “u”; toggling up yields “v”; toggling right yields “w”; toggling down yields “x”; and depressing yields “y”. Key 110J may be configured so that depressing yields “z”.

For entering numeric data, key 110F may be configured so that: toggling left yields “1”; toggling up yields “2”; toggling right yields “3”; toggling down yields “4”; and depressing yields “5”. Key 110G may be configured so that: toggling left yields “6”; toggling up yields “7”; toggling right yields “8”; toggling down yields “9”; and depressing yields “0”.

If the number of primary keys 110 is not sufficient to enter all responses of the response set, more primary keys may be added, or a secondary key such as the thumb key 112 illustrated may be added and made to operate so that it shifts or causes the primary keys 110 to produce different responses for completing the response set. The secondary key preferably is a five-position key like the primary keys, so the thumb key quintuples the maximum size of the response set. It may be programmed to provide the functions provided by the “Shift”, “Ctrl” and “Alt” buttons on a conventional keyboard, or otherwise to redefine the character mapping of the primary keys. For example, one position of the secondary key may produce upper case equivalents of the lower case letters listed two paragraphs above.

Apparatus 100 also may include a legend 115 proximally associated with one or more of keys 110, showing entries associated with actuation directions thereof as a teaching aid. Legend 115 may be displayed on a stand-alone sheet 120 that is selectably mountable on keyboard 105.

The apparatus preferably includes appropriate circuitry and instrumentation to facilitate communication with a variety of electronic devices, in particular, but not limited to cellular telephones and personal digital assistants. Such communication may be performed via wired, infrared, radio, Bluetooth® or other wired or wireless communication methods.

The apparatus 100 may also include its own output screen 125, such as a liquid crystal display device, for monitoring input as entered.

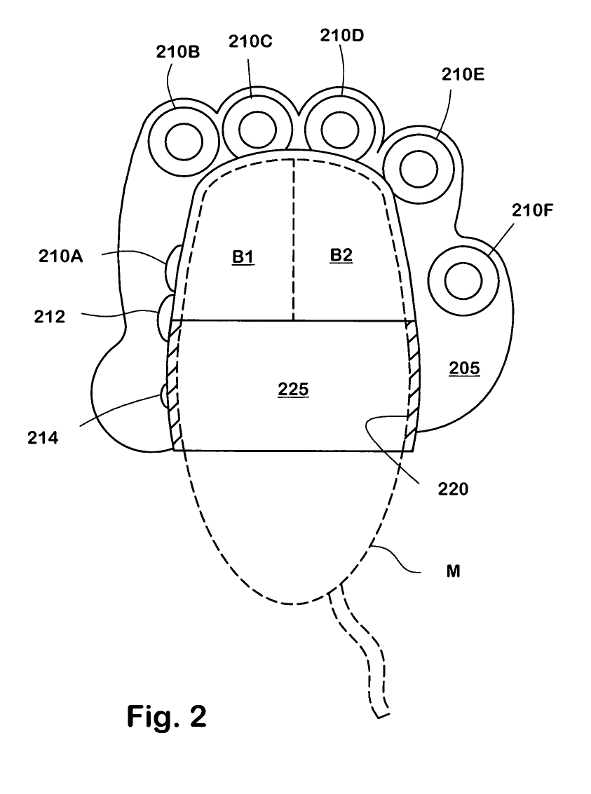

FIG. 2 shows another embodiment of the invention. This version includes a base 205 on or in which are mounted a plurality of keys 210.

The keys 210 are arranged ergonomically. Keys 210A-F are spaced and oriented to be where a typical user's fingers naturally will contact keys 210 in a relaxed or normal state. Preferably, a user's index finger operates keys 210B and 210C, and the remaining fingers operate keys 210D-210F, while the user's thumb operates key 210A. The user's thumb may alternatively operate key 212 for entering frequently-used entries, for example, “space,” “tab right,” tab left” and “return.” While the apparatus shown is configured for right-handed operation, a left-handed configuration is contemplated as well.

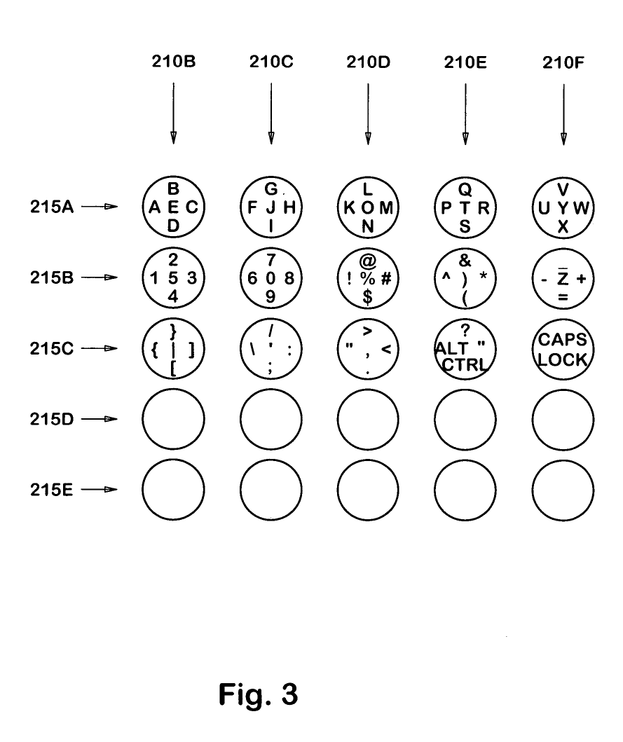

In the apparatus of FIG. 3, each key 210 is actuable in at least five directions. For example, as shown in row 215A, key 210B may be configured so that: toggling left yields “a”; toggling up yields “b”; toggling right yields “c”; toggling down yields “d”; and depressing yields “e”. Key 210C may be configured so that: toggling left yields “f”; toggling up yields “g”; toggling right yields “h”; toggling down yields “i”; and depressing yields “j”. Key 210D may be configured so that: toggling left yields “k”; toggling up yields “l”; toggling right yields “m”; toggling down yields “n”; and depressing yields “o”. Key 210E may be configured so that: toggling left yields “p”; toggling up yields “q”; toggling right yields “r”; toggling down yields “s”; and depressing yields “t”. Key 210F may be configured so that: toggling left yields “u”; toggling up yields “v”; toggling right yields “w”; toggling down yields “x”; and depressing yields “y”.

Key 210A provides for shifting to a different set of characters or operations associated with actuation of keys 210B-F. As with the other keys 210, key 210A is configured to toggle left, toggle up, toggle right, toggles down and depress. Examples of providing for shifting may involve any of the foregoing actuation modes.

As shown in row 215B in FIG. 3, when key 210A is actuated to induce a first shifting mode, key 210B may be configured so that: toggling left yields “1”; toggling up yields “2”; toggling right yields “3”; toggling down yields “4”; and depressing yields “5”. Key 210C may be configured so that: toggling left yields “6”; toggling up yields “7”; toggling right yields “8”; toggling down yields “9”; and depressing yields “0”. Key 210D may be configured so that: toggling left yields “!”; toggling up yields “@”; toggling right yields “#”; toggling down yields “$”; and depressing yields “%”. Key 210E may be configured so that: toggling left yields “ˆ”; toggling up yields “&”; toggling right yields “*”; toggling down yields “(”; and depressing yields “)”. Key 210F may be configured so that: toggling left yields “-”; toggling up yields “_”; toggling right yields “+”; toggling down yields “=”; and depressing yields “z”.

As shown in row 215C in FIG. 3, when key 210A is actuated to induce a second shifting mode, key 210B may be configured so that: toggling left yields “{”; toggling up yields “}”; toggling right yields “]”; toggling down yields “[”; and depressing yields “|”. Key 210C may be configured so that: toggling left yields “\”; toggling up yields “/”; toggling right yields “:”; toggling down yields “;”; and depressing yields “'”. Key 210D may be configured so that: toggling left yields ““”; toggling up yields “>”; toggling right yields “<”; toggling down yields “.”; and depressing yields “,”. Key 210E may be configured so that: toggling left induces an “ALT” operation; toggling up yields “?”; toggling right yields “””; and toggling down induces a “CTRL” operation. Key 210F may be configured so that depressing it induces a “CAPS LOCK” operation.

It should be understood that all the key assignments listed above are only examples, and that any layout is possible, just as there are well-known variations from the “qwerty” scheme for conventional keyboards. The important point is that each input device is capable of generating several responses so that information can be entered with one hand.

The apparatus shown in FIG. 2 is configured to receive a conventional or custom-made mouse M. To perform this function, it can have an inverted “U” shape, or may be sculpted with a concavity providing sufficient clearance to securely, selectably mount on the mouse M, and provide appropriate access to the conventional buttons B typically provided on a mouse. Preferably, the apparatus has pads 220 that cooperatively grip and positively position mouse M. It preferably also includes a palm rest 225 configured to provide sufficient clearance for mouse M and sturdy support for a user's hand. The palm rest 225 is adjustable to raise or lower same as necessary for users of differing hand sizes. A brake (not shown) may be activated by depressing a button 214 to selectively prevent the apparatus from moving relative to a work surface.

The apparatus could, in lieu of a mouse, have a roller ball (not shown) or the like.

As with apparatus the device shown in FIG. 1, the apparatus 200 also may include a legend on a sheet showing the key assignments, for training.

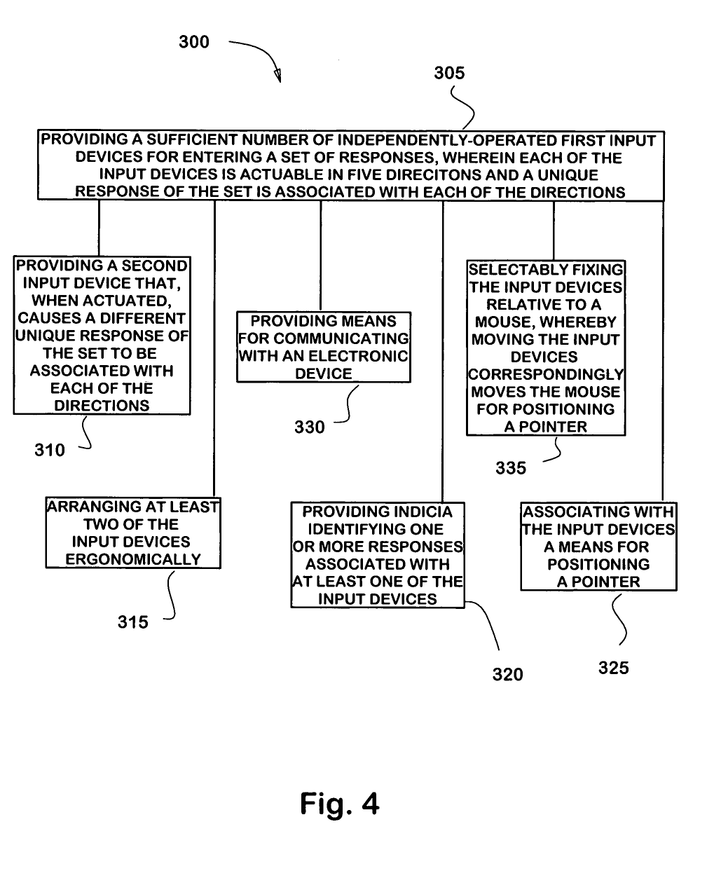

FIG. 4 shows schematically a method 300 which includes a step 305 of providing a sufficient number of independently-operated input devices for entering a set of responses. Each of the input devices is actuable in five directions. A unique response of the set is associated with each of the directions. In FIG. 3, row 215A shows how five input devices may be actuated in five distinct directions to enter the English-language characters “a” through “y”.

The method preferably also includes a step 310 of providing a second input device that, when actuated, causes a different unique response of the set to be associated with each of the directions. That is, the secondary input device shifts the key assignments of the primary input devices. Most commonly, the primary input devices are finger buttons, and the secondary input device is a thumb button. A non-exclusive example of this may be understood from FIG. 3, row 215B, which shows that a right-most input device may be actuated in a distinct direction to enter the English-language character “z”.

At least two of the first input devices are arranged ergonomically (step 315). An example of this is shown in FIG. 2, wherein input devices 210B-F are spaced and oriented to be where a typical user's fingers naturally would contact input devices 210 in a relaxed or normal state.

Markings are preferably made relative to at least one of the input device (step 320), for identifying one or more responses associated actuation. An example of this is described above and shown in FIG. 1, wherein a legend 115 is displayed on a stand-alone sheet 120 selectably mountable on keyboard 105.

The input devices may be associated (step 325) with a mouse or similar device for positioning a pointer. Such devices, which are well known, may be adapted for use with systems yet to be developed.

One may also provide means for communicating with an electronic device (step 330). Suitable technology for providing such communication, being well know to those of skill in the field of this invention, is not described in detail.

When the five input devices are fixed relative to a mouse (step 335), moving the five input devices correspondingly moves the mouse and thus the pointer. An example of this is described above and shown in FIG. 2, wherein apparatus 200 selectably mounts on or receives mouse M.

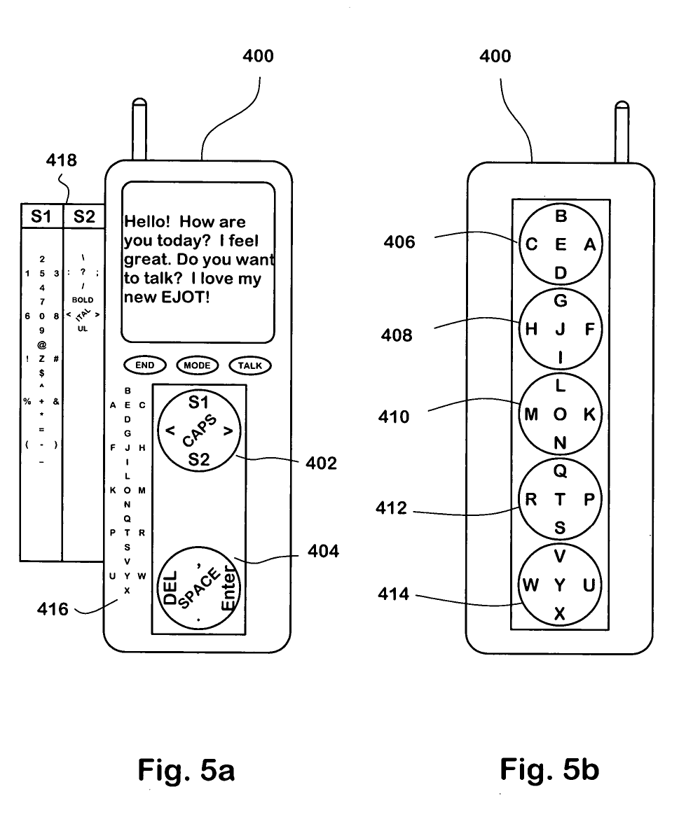

FIGS. 5a and 5b depict the front and rear of a cell phone 400 having primary and secondary input entry keys. The key 402 on the front of the phone is a secondary input key for the thumb. The lower thumb key 404 on the front of the phone and the five finger keys 406, 408, 410, 412, 414 on the rear (outside) of the cell phone are primary keys. All of the keys illustrated are of the toggle type described above: each can be depressed, or tilted in any of four directions, to generate a desired character, so that 25 different characters can be generated with the finger keys alone. With the upper thumb key 402, one selects either mode S1 or S2, which extend the range of characters to include “Z”, the numerals, and common punctuation, as well a bold, italic, and underline modes. Depressing key 402 produces capitalization. Delete and enter commands are obtained by left or right movements of key 404, and spaces are generated by pressing key 404. The thumb can be placed between keys 402 and 404 when they are not being used.

One cannot see the finger keys during normal cell phone use, so to assist the user while he is learning the character locations on the keys, the characters are printed on the phone surface 416, adjacent the thumb keys. The alternative S1 and S2 character sets are printed on a fold-out panel 418 for reference. In each case, the printed legend is a mirror image of the characters on the finger keys to make the legend easy to follow.

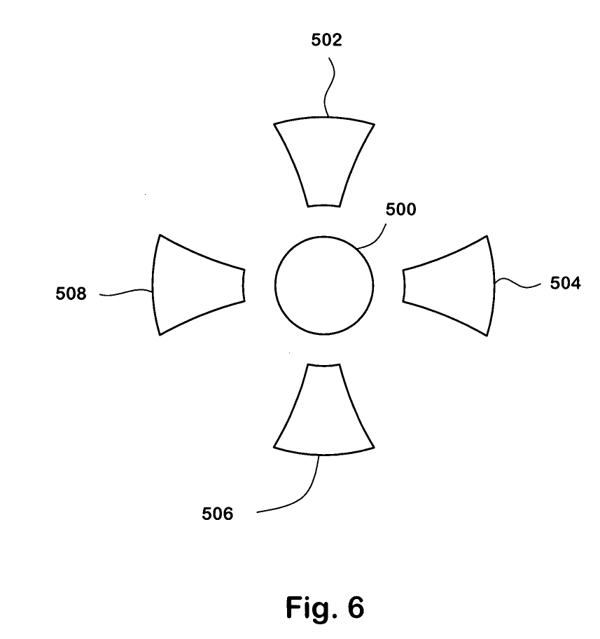

While all the above examples depict the input devices as round buttons or keys which can be tilted or depressed to generate five different responses, each input device could alternatively comprise five small buttons, as illustrated in FIG. 6. The center button 500 is surrounded by four outer buttons 502, 504, 506 and 508. An advantage of this arrangement is that one could provide more or fewer outer buttons to produce a corresponding increase or decrease in the number of possible responses. Otherwise, the same function as a single five-position button is obtained.

Inasmuch as the invention is not limited to the particular embodiments described and depicted herein, it is intended that the invention should be measured by the following claims.

I claim:

1. An apparatus for entering data comprising a number of primary independently-operated input devices for entering a set of responses, wherein:
each of said primary input devices is actuable in at least five directions; and
a unique response of the set is associated with each of the directions.

2. An apparatus as recited in claim 1, further comprising a secondary input device that, when actuated, causes a different unique response of the set to be associated with each of the directions of each of the primary input devices.

3. An apparatus as recited in claim 1, wherein the set of responses is selected from the English-language alphabet, Arabic numerals, diacritical marks commonly associated therewith and combinations thereof.

4. An apparatus as recited in claim 1, further comprising a secondary input device that is operable as a joy stick.

5. An apparatus as recited in claim 1, wherein said input devices are arranged ergonomically.

6. An apparatus as recited in claim 1, further comprising key disposed relative to at least one of said input device, for identifying one or more responses associated with actuation thereof.

7. An apparatus as recited in claim 1, further comprising means for communicating with an electronic device.

8. An apparatus as recited in claim 1, configured to receive a mouse, whereby moving said apparatus correspondingly moves the mouse for positioning a pointer.

9. An apparatus as recited in claim 1, further comprising a brake for selectively fixing said apparatus relative to a work surface.

10. An apparatus as recited in claim 1, further comprising means for positioning a pointer.

11. An apparatus for entering data comprising one or more input devices, wherein:
each of said input devices is actuable in at least one of a plurality of directions;
a unique response is associated with each of the plurality of directions; and
said apparatus is configured to receive a mouse.

12. An apparatus as recited in claim 11, further comprising a second input device that, when actuated, causes a different unique response of the set to be associated with each of the plurality of directions.

13. An apparatus as recited in claim 11, further comprising key disposed relative to at least one, for identifying one or more responses associated with actuation, of said input devices.

14. An apparatus as recited in claim 11, wherein said input devices are arranged ergonomically.

15. An apparatus as recited in claim 11, further comprising means for communicating with an electronic device.

16. An apparatus as recited in claim 11, further comprising a brake for selectively fixing said apparatus relative to a work surface.

17. A method of entering data comprising providing a sufficient number of independently-operated input devices for entering a set of responses, wherein:
each of the input devices is actuable in five directions; and
a unique response of the set is associated with each of the directions.

18. A method as recited in claim 17, further comprising providing a second input device that, when actuated, causes a different unique response of the set to be associated with each of the directions.

19. A method as recited in claim 18, wherein the set is selected from the English-language alphabet, Arabic numerals, diacritical marks commonly associated therewith and combinations thereof.
